(19) United States
(12) Patent Application Publication
(10) Pub. No.: US 2026/0181284 A1
(43) Pub. Date: Jun. 25, 2026

(54) LIGHT DETECTION DEVICE, METHOD FOR CONTROLLING LIGHT DETECTION DEVICE, AND ELECTRONIC APPARATUS

(71) Applicant: SONY SEMICONDUCTOR SOLUTIONS CORPORATION, KANAGAWA (JP)

(72) Inventor: KENICHI OKUMURA, KANAGAWA (JP)

(21) Appl. No.: 19/127,131

(22) PCT Filed: Nov. 8, 2022
(86) PCT No.: PCT/JP2022/041572

§ 371 Date: May 5, 2025

(51) Int. Cl. H04N 25/772; H04N 25/76

(52) U.S. Cl. CPC H04N 25/772; H04N 25/7795

(57) ABSTRACT

Provided is a light detection device capable of achieving pixel miniaturization and improving pixel characteristics. The light detection device includes a plurality of pixels. Each of the plurality of pixels includes a photoelectric conversion film, a first charge accumulation section, a transfer transistor, a second charge accumulation section, and a potential difference generation section. The photoelectric conversion film generates a signal charge of an amount corresponding to incident light. The first charge accumulation section is connected to the photoelectric conversion film, and receives and accumulates signal charges. The transfer transistor transfers the signal charges accumulated in the first charge accumulation section. The second charge accumulation section accumulates the signal charges transferred by the transfer transistor. The potential difference generation section generates a potential difference between the first charge accumulation section and the second charge accumulation section. The gate voltage of the transfer transistor is set to be switched to a first voltage to be turned on, a second voltage to be turned off, and a third voltage at which signal charges overflow from the first charge accumulation section to the second charge accumulation section between the first voltage and the second voltage.

### TECHNICAL FIELD

The technology (present technology) according to the present disclosure relates to a light detection device, a method for controlling a light detection device, and an electronic apparatus including a light detection device.

### BACKGROUND ART

In an infrared sensor, a capacitive trans impedance amplifier (CTIA) circuit is generally used. Since a bias (film bias) applied to a photoelectric conversion film is a constant voltage, characteristics are good, but pixel miniaturization is difficult in terms of the number of circuit elements and power.

In pixel miniaturization, a floating diffusion (FD) retention type circuit is advantageous in terms of the number of elements and power (for example, Patent Document 1).

### CITATION LIST

### Patent Document

Patent Document 1: Japanese Patent Application Laid-Open No. 2021-90112

### SUMMARY OF THE INVENTION

### Problems to be Solved by the Invention

However, even in the FD retention type circuit disclosed in Patent Document 1, the film bias voltage changes as charges are accumulated, and the film capacitance also varies. Therefore, the linearity is not good.

Furthermore, even in the FD retention type circuit disclosed in Patent Document 1, it is difficult to increase the saturation charge amount (capacitance×film bias) for the following reasons.
(1) When the film bias is high, the dark current increases, so that the voltage cannot be increased.
(2) When the capacity is increased, the conversion efficiency decreases and the noise characteristics deteriorate. Furthermore, it is difficult in terms of miniaturization because it takes an area.

The present disclosure has been made in view of such circumstances, and an object of the present disclosure is to provide a light detection device, a method for controlling a light detection device, and an electronic apparatus capable of achieving pixel miniaturization and improving pixel characteristics.

### Solutions to Problems

An aspect of the present disclosure is a light detection device including a pixel array section in which a plurality of pixels is arranged in an array. Each of the plurality of pixels includes: a photoelectric conversion film that generates a signal charge of an amount corresponding to light incident from an outside; a first charge accumulation section that is connected to the photoelectric conversion film and receives and accumulates the signal charge; a transfer transistor that is connected to the photoelectric conversion film and the first charge accumulation section and transfers the signal charge accumulated in the first charge accumulation section; a second charge accumulation section that temporarily accumulates signal charges transferred by the transfer transistor; and a potential difference generation section that generates a potential difference between the first charge accumulation section and the second charge accumulation section. A gate voltage of the transfer transistor is set to be switched to a first voltage to be turned on, a second voltage to be turned off and lower than the first voltage, and a third voltage between the first voltage and the second voltage, the third voltage causing the signal charge to overflow from the first charge accumulation section to the second charge accumulation section.

Another aspect of the present disclosure is a method for controlling a light detection device including a pixel array section in which a plurality of pixels is arranged in an array. The method includes: generating a signal charge of an amount corresponding to light incident from an outside by a photoelectric conversion film included in each of the plurality of pixels; setting a first charge accumulation section that receives and accumulates the signal charge generated by the photoelectric conversion film and a second charge accumulation section that temporarily accumulates a signal charge transferred by a transfer transistor to a same potential; setting the first charge accumulation section and the second charge accumulation section to different potentials at least during an accumulation period of the signal charge; setting a gate voltage of the transfer transistor to be switched to a third voltage at which the signal charge overflows from the first charge accumulation section to the second charge accumulation section between a first voltage to be turned on and a second voltage to be turned off and lower than the first voltage during a period in which the first charge accumulation section and the second charge accumulation section are set to different potentials; and setting a gate voltage of the transfer transistor to be switched from the third voltage to the first voltage or the second voltage at a time of reading the signal charge.

Moreover, another aspect of the present disclosure is an electronic apparatus including a light detection device and a control unit configured to perform control on the basis of a pixel signal based on a signal charge read out by the light detection device. The light detection device includes: a pixel array section in which a plurality of pixels is arranged in an array. Each of the plurality of pixels includes: a photoelectric conversion film that generates a signal charge of an amount corresponding to light incident from an outside; a first charge accumulation section that is connected to the photoelectric conversion film and receives and accumulates the signal charge; a transfer transistor that is connected to the photoelectric conversion film and the first charge accumulation section and transfers the signal charge accumulated in the first charge accumulation section; a second charge accumulation section that temporarily accumulates signal charges transferred by the transfer transistor; and a potential difference generation section that generates a potential difference between the first charge accumulation section and the second charge accumulation section. A gate voltage of the transfer transistor is set to be switched to a first voltage to be turned on, a second voltage to be turned off and lower than the first voltage, and a third voltage between the first voltage and the second voltage, the third voltage causing the signal charge to overflow from the first charge accumulation section to the second charge accumulation section.

### BRIEF DESCRIPTION OF DRAWINGS

FIG. 1 is a block diagram illustrating an example of a schematic configuration of a light detection device according to a first embodiment of the present disclosure.

FIG. 2 is an example of a circuit configuration diagram of the pixel illustrated in FIG. 1.

FIG. 3 is a timing chart illustrating an example of operation of pixels in a pixel array section of the light detection device according to the first embodiment of the present disclosure.

FIG. 4A is a diagram (part 1) illustrating a potential diagram at each time in the timing chart of FIG. 3.

FIG. 4B is a diagram (part 2) illustrating a potential diagram at each time in the timing chart of FIG. 3.

FIG. 4C is a diagram (part 3) illustrating a potential diagram at each time in the timing chart of FIG. 3.

FIG. 5 is an example of a circuit configuration diagram of a pixel according to a second embodiment of the present disclosure.

FIG. 6 is a timing chart illustrating an example of operation of pixels in a pixel array section of the light detection device according to the second embodiment of the present disclosure.

FIG. 7A is a diagram (part 1) illustrating a potential diagram at each time in the timing chart of FIG. 6.

FIG. 7B is a diagram (part 2) illustrating a potential diagram at each time in the timing chart of FIG. 6.

FIG. 7C is a diagram (part 3) illustrating a potential diagram at each time in the timing chart of FIG. 6.

FIG. 8 is an example of a circuit configuration diagram of a pixel according to a third embodiment of the present disclosure.

FIG. 9 is a timing chart illustrating an example of operation of pixels in a pixel array section of the light detection device according to the third embodiment of the present disclosure.

FIG. 10A is a diagram (part 1) illustrating a potential diagram at each time in the timing chart of FIG. 9.

FIG. 10B is a diagram (part 2) illustrating a potential diagram at each time in the timing chart of FIG. 9.

FIG. 10C is a diagram (part 3) illustrating a potential diagram at each time in the timing chart of FIG. 9.

FIG. 11 is an example of a circuit configuration diagram of a pixel according to a fourth embodiment of the present disclosure.

FIG. 12 is an example of a circuit configuration diagram of a pixel according to a fifth embodiment of the present disclosure.

FIG. 13 is an example of a circuit configuration diagram of a pixel according to a sixth embodiment of the present disclosure.

FIG. 14 is an example of a circuit configuration diagram of a pixel according to a seventh embodiment of the present disclosure.

FIG. 15 is an example of a circuit configuration diagram of a pixel according to an eighth embodiment of the present disclosure.

FIG. 16 is a block diagram illustrating an example of a schematic configuration of a light detection device according to a ninth embodiment of the present disclosure.

FIG. 17 is a flowchart illustrating a control processing procedure of a control logic circuit according to the ninth embodiment of the present disclosure.

FIG. 18 is a block diagram illustrating a configuration example of an imaging device as an electronic apparatus to which the present technology is applied.

FIG. 19 is a block diagram illustrating a schematic configuration example of a vehicle control system, which is an example of a mobile object control system to which the technology according to the present disclosure may be applied.

FIG. 20 is a diagram illustrating an example of an installation position of an imaging section illustrated in FIG. 19.

### MODE FOR CARRYING OUT THE INVENTION

Hereinafter, embodiments of the present disclosure will be described with reference to the drawings. In the description of the drawings referred to in the following description, the same or similar parts are denoted by the same or similar reference signs to avoid the description from being redundant. However, it should be noted that the drawings are schematic, and the relationship between thickness and planar dimension, the proportion of thickness of each device or each member, and the like differ from actual ones. Therefore, specific thicknesses and dimensions should be determined in consideration of the following description. Furthermore, it is needless to say that the drawings include portions having different dimensional relationships and ratios.

In this specification, a “first conductivity type” means one of a p-type or an n-type, and a “second conductivity type” means one of the p-type or the n-type different from the “first conductivity type”.

Furthermore, the definitions of directions such as up and down or the like in the following description are merely definitions for convenience of description, and do not limit the technical idea of the present disclosure. For example, it is a matter of course that when an object is observed by rotating the object by 90°, the up and down are converted into and read as left and right, and when the object is observed by rotating the object by 180°, the up and down are inverted and read.

Note that the effects described in the present specification are merely examples and are not limited, and other effects may be provided.

### First Embodiment

### Overall Configuration of Light Detection Device

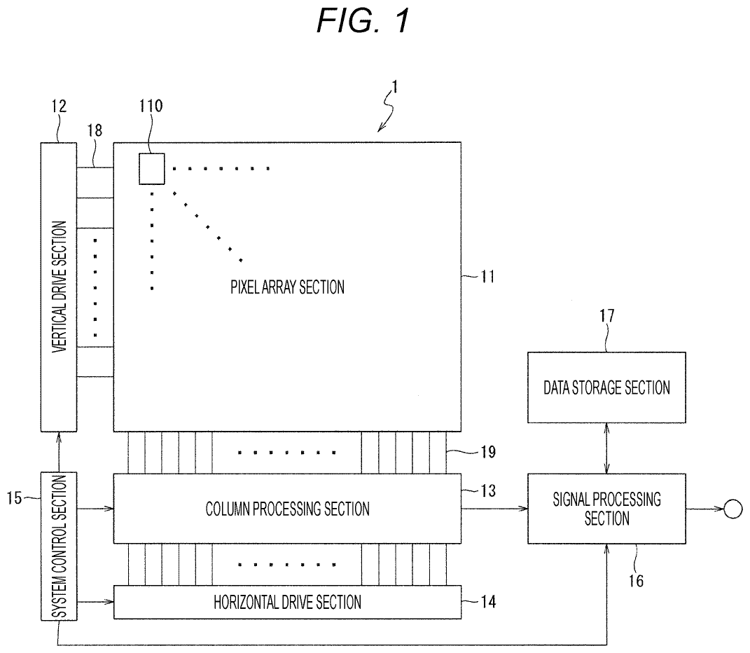

FIG. 1 is a block diagram depicting an example of a schematic configuration of a light detection device according to a first embodiment of the present disclosure. A light detection device 1 is a semiconductor device that converts a charge amount corresponding to the intensity of light formed as an image on each pixel into an electric signal using a photoelectric conversion film constituting each pixel, and outputs the electric signal as image data, and is configured as, for example, a CMOS image sensor. The light detection device 1 can be integrally configured as, for example, a system on a chip (SoC) such as a CMOS LSI, but for example, some components described below may be configured as separate LSIs.

As depicted in the drawing, the light detection device 1 includes components such as a pixel array section 11, a vertical drive section 12, a column processing section 13, a horizontal drive section 14, a system control section 15, a signal processing section 16, and a data storage section 17, for example.

The pixel array section 11 includes a photoelectric conversion element group such as photodiodes forming pixels 110 arrayed in a horizontal direction (row direction) and a vertical direction (column direction). The pixel array section 11 converts a charge amount corresponding to intensity of incident light formed as an image on each pixel 110 into an electric signal and outputs the same as a pixel signal. The pixel array section 11 can include, for example, effective pixels arranged in a region capable of receiving actual light and dummy pixels arranged outside the region and shielded by metal and the like. Note that, an optical element such as a micro-on-chip lens or a color filter that condenses incident light is formed on each pixel 110 of the pixel array section 11 (not depicted).

The vertical drive section 12 includes a shift register, an address decoder, and the like. The vertical drive section 12 supplies a drive signal and the like to each pixel 110 via a plurality of pixel drive lines 18, thereby driving each pixel 110 of the pixel array section 11, for example, simultaneously or row by row.

The column processing section 13 reads a pixel signal from each pixel 110 via a vertical signal line (VSL) 19 for each pixel column of the pixel array section 11, and performs noise removal processing, correlated double sampling (CDS) processing, analog-to-digital (A/D) conversion processing, and the like. The pixel signal processed by the column processing section 13 is output to the signal processing section 16. As described later, the column processing section 13 performs AD conversion processing on the basis of a pixel signal in a pre-charge phase (hereinafter, referred to as a “P-phase”) and a pixel signal in a data phase (hereinafter, referred to as a “D-phase”).

The horizontal drive section 14 includes a shift register, an address decoder, and the like. The horizontal drive section 14 sequentially selects the pixels 110 corresponding to the pixel columns of the column processing section 13. By selective scanning by the horizontal drive section 14, the pixel signals subjected to the signal processing for each pixel 110 in the column processing section 13 are sequentially output to the signal processing section 16.

The system control section 15 includes a timing generator that generates various timing signals and the like. The system control section 15 performs drive control of the vertical drive section 12, the column processing section 13, and the horizontal drive section 14 on the basis of, for example, a timing signal generated by a timing generator not depicted.

The signal processing section 16 performs signal processing such as arithmetic processing on the pixel signal supplied from the column processing section 13 while temporarily storing data in the data storage section 17 as necessary, and outputs an image signal based on each pixel signal. Furthermore, the signal processing section 16 performs the signal processing according to a flag output from the column processing section 13.

Note that, the light detection device 1 to which the present technology is applied is not limited to the configuration as described above. For example, the light detection device 1 may be configured such that the data storage section 17 is arranged at a subsequent stage of the column processing section 13, and the pixel signal output from the column processing section 13 is supplied to the signal processing section 16 via the data storage section 17. Alternatively, the light detection device 1 may be configured in such a manner that the column processing section 13, the data storage section 17, and the signal processing section 16 connected in cascade process the respective pixel signals in parallel.

### Circuit Configuration of Pixel

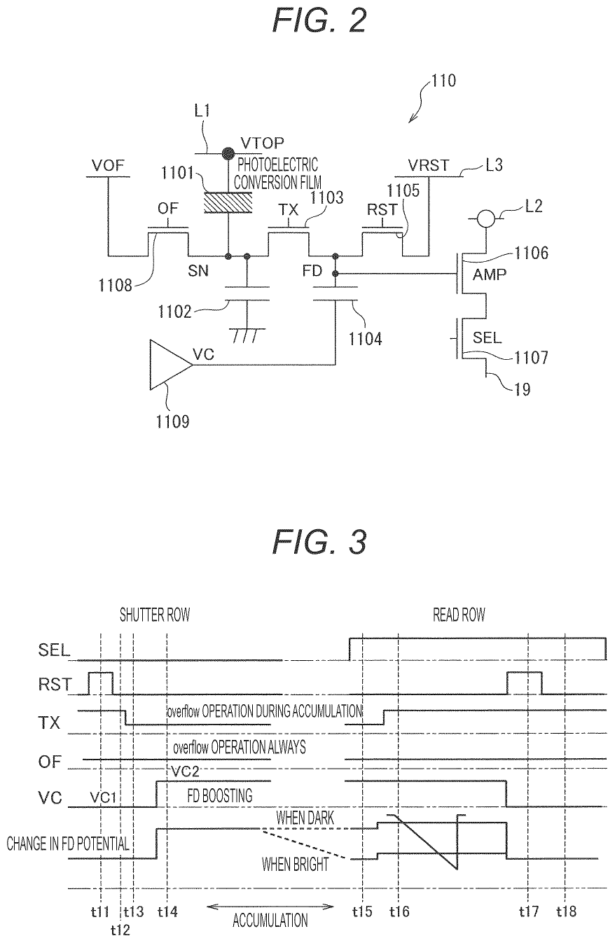

FIG. 2 is an example of a circuit configuration diagram of the pixel 110. That is, this drawing illustrates an example of a circuit configuration of any one pixel 110 among the plurality of pixels 110 constituting the pixel array section 11 of the light detection device 1 illustrated in FIG. 1.

The pixel 110 includes a photoelectric conversion film 1101 containing, for example, an inorganic material such as InGaAs, an organic material, a quantum dot, or the like. Furthermore, in the present disclosure, the pixel 110 is configured to be capable of outputting a signal charge generated by the photoelectric conversion film 1101 according to the intensity of received light as a pixel signal. One end of the photoelectric conversion film 1101 is connected to a power supply line L1 that supplies a power supply voltage (VTOP).

Furthermore, the pixel 110 of the present example includes a first charge accumulation region (SN) 1102, a transfer transistor 1103, a second charge accumulation region (FD) 1104, a reset transistor 1105, an amplification transistor (AMP) 1106, a selection transistor 1107, a charge discharge transistor 1108, and a voltage generation circuit 1109. In this example, the transfer transistor 1103, the reset transistor 1105, the amplification transistor (AMP) 1106, the selection transistor 1107, and the charge discharge transistor 1108 are N-channel MOS transistors that handle electrons as signal charges.

Furthermore, a plurality of drive lines for supplying various drive signals TX, RST, OF, SEL, and VC to the pixel 110 is wired, for example, for each pixel row as the pixel drive lines 18 illustrated in FIG. 1. These drive signals are, for example, pulse signals that bring the N-channel MOS transistor into a conductive (on) state at a high potential level and bring the N-channel MOS transistor into a non-conductive (off) state at a low potential level.

The first charge accumulation region (SN) 1102 includes capacitors such as CI capacitance, wiring capacitance, and parasitic capacitance in the film. One electrode of the first charge accumulation region (SN) 1102 is connected to the other end of the photoelectric conversion film 1101 and the drain electrode of the transfer transistor 1103, and the other electrode is connected to the ground (GND). The first charge accumulation region (SN) 1102 accumulates signal charges photoelectrically converted by the photoelectric conversion film 1101.

The transfer transistor 1103 is an N-channel MOS transistor provided between the photoelectric conversion film 1101 and the second charge accumulation region (FD) 1104. The voltage of the drive signal TX is applied to a gate electrode of the transfer transistor 1103. That is, when the drive signal TX exceeds a high potential level, that is, a gate-source threshold voltage, the transfer transistor 1103 enters a conductive state, and the signal charge accumulated in the first charge accumulation region (SN) 1102 is transferred to the second charge accumulation region (FD) 1104 via the transfer transistor 1103.

The second charge accumulation region (FD) 1104 is a floating diffusion region capable of holding a predetermined charge amount, and accumulates signal charges transferred by the transfer transistor 1103. One electrode of the second charge accumulation region (FD) 1104 is connected to the voltage generation circuit 1109, and the other electrode is connected to each of the drain electrode of the transfer transistor 1103, the source electrode of the reset transistor 1105, and the gate electrode of the amplification transistor 1106. The signal charge accumulated in the second charge accumulation region (FD) 1104 is read out by charge-voltage conversion into a voltage signal.

The amplification transistor 1106 is an N-channel MOS transistor connected to the second charge accumulation region (FD) 1104 and having a drain electrode connected to a power supply line L2 that supplies a power supply voltage. The amplification transistor 1106 serves as an input section of a reading circuit for reading signal charges held in the second charge accumulation region (FD) 1104, that is, a source follower circuit. That is, the source electrode of the amplification transistor 1106 is connected to the vertical signal line 19 via the selection transistor 1107.

The selection transistor 1107 is an N-channel MOS transistor provided between the source electrode of the amplification transistor 1106 and the vertical signal line 19. The drive signal SEL is applied to the gate electrode of the selection transistor 1107. When the drive signal SEL reaches a high potential level, the selection transistor 1107 enters a conductive state, and the pixel 110 enters a selected state. As a result, the pixel signal output from the amplification transistor 1106 is read out to the vertical signal line 19 via the selection transistor 1107.

The reset transistor 1105 is an N-channel MOS transistor provided between a reset power supply line L3 that supplies a reset power supply voltage VRST and the second charge accumulation region (FD) 1104. The voltage of the drive signal RST is applied to a gate electrode of the reset transistor 1105. When the drive signal RST reaches a high potential level, the reset transistor 1105 enters a conductive state. As a result, the potentials of the first charge accumulation region (SN) 1102 and the second charge accumulation region (FD) 1104 are reset to the reset power supply voltage VRST.

The charge discharge transistor 1108 is an N-channel MOS transistor provided between a power supply line L4 that supplies a power supply voltage VOF and the first charge accumulation region (SN) 1102. The voltage of the drive signal OF is applied to the gate electrode of the charge discharge transistor 1108. When the drive signal OF reaches a high potential level, the charge discharge transistor 1108 enters a conductive state. As a result, the signal charges remaining in the first charge accumulation region (SN) 1102 are discharged to the power supply line L4.

The voltage generation circuit 1109 is a circuit that generates a potential difference between the first charge accumulation region (SN) 1102 and the second charge accumulation region (FD) 1104.

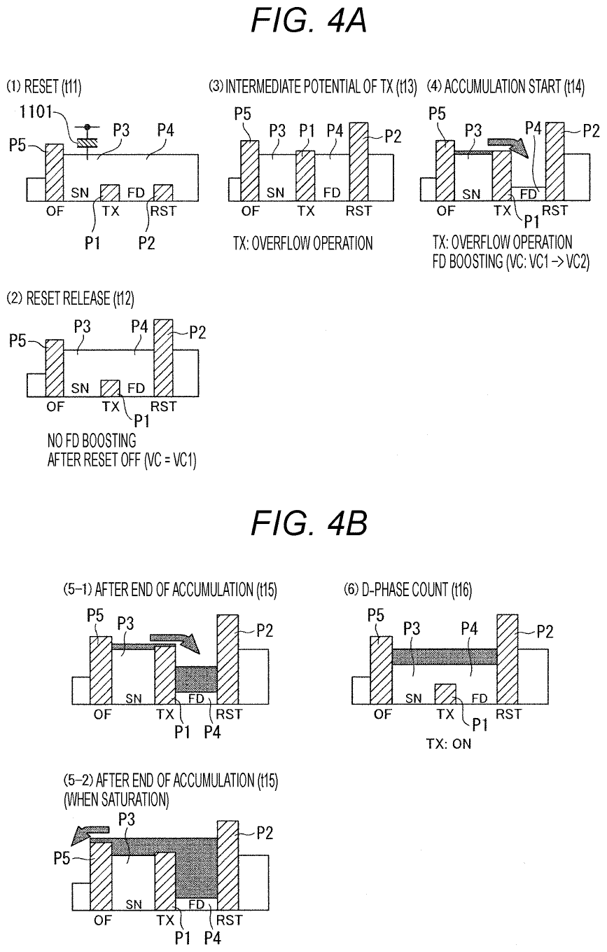

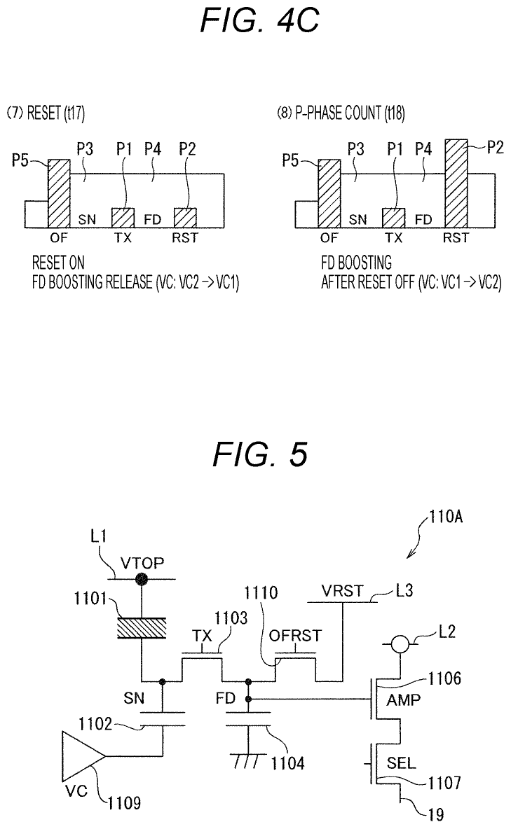

FIG. 3 is a timing chart depicting an example of the operation of the pixel in the pixel array section of the light detection device according to the first embodiment of the present disclosure, and specifically, is a timing chart depicting an example of processing related to exposure (light reception) by each pixel 110. In the drawing, a timing chart of the drive signals SEL, RST, TX, OF, and VC is illustrated (see FIG. 2). FIGS. 4A to 4C illustrate potential diagrams at each time in the timing chart of FIG. 3.

First, at time t11, the drive signals RST and TX reaches a high potential level, and the reset transistor 1105 and the transfer transistor 1103 enter the conductive state. Furthermore, by setting the VC voltage generated by the voltage generation circuit 1109 to VC1, the first charge accumulation region (SN) 1102 and the second charge accumulation region (FD) 1104 are reset to the reset power supply voltage VRST. At this time, as illustrated in (1) of FIG. 4A, a potential barrier P1 corresponding to the transfer transistor 1103 and a potential barrier P2 corresponding to the reset transistor 1105 are lowered, and potential barriers P3 and P4 corresponding to the first charge accumulation region (SN) 1102 and the second charge accumulation region (FD) 1104, respectively, are higher than the potential barriers P1 and P2. Note that the potential barriers P3 and P4 are lower than a potential barrier P5 corresponding to the charge discharge transistor 1108 in the non-conductive state.

Next, at time t12, the drive signal RST is at a low potential level, that is, the gate voltage of the reset transistor 1105 becomes less than the gate-source threshold voltage, and the reset transistor 1105 enters a non-conductive state. At this time, as illustrated in (2) of FIG. 4A, the potential barrier P2 corresponding to the reset transistor 1105 returns to the original height and becomes higher than the potential barriers P3 and P4.

Next, at time t13, the drive signal TX is at a low potential level, that is, the gate voltage of the transfer transistor 1103 becomes less than the gate-source threshold voltage, and the transfer transistor 1103 enters a non-conductive state. At this time, as illustrated in (3) of FIG. 4A, the gate voltage of the transfer transistor 1103 is set to an intermediate voltage around the gate-source threshold voltage. The threshold voltage at this time is a voltage that does not exceed the threshold voltage of the charge discharge transistor 1108, and the potential difference is set within 1 V, for example. Note that the potential barrier P1 corresponding to the transfer transistor 1103 is higher than the potential barriers P3 and P4.

Next, at time t14, the VC voltage generated by the voltage generation circuit 1109 is set to VC2 higher than VC1. At this time, as illustrated in (4) of FIG. 4A, the voltage applied to the second charge accumulation region (FD) 1104 is boosted, and the potential barrier P4 corresponding to the second charge accumulation region (FD) 1104 becomes lower than the potential barrier P3 corresponding to the first charge accumulation region (SN) 1102. As a result, the signal charge generated in the photoelectric conversion film 1101 overflows the first charge accumulation region (SN) 1102 and the transfer transistor 1103 and is accumulated in the second charge accumulation region (FD) 1104.

Next, at time t15, the drive signal SEL reaches a high potential level, and the selection transistor 1107 enters a conductive state. At this time, as illustrated in (5-1) of FIG. 4B, during the accumulation period, the VC voltage is held at VC2, the gate voltage of the transfer transistor 1103 is also held at the intermediate voltage, the signal charge is accumulated in the second charge accumulation region (FD) 1104, and the potential of the first charge accumulation region (SN) 1102 is kept constant. In (5-1) of FIG. 4B, a pixel signal corresponding to dark light is output from the selection transistor 1107.

On the other hand, as illustrated in (5-2) of FIG. 4B, when the potential of the second charge accumulation region (FD) 1104 exceeds the intermediate voltage of the transfer transistor 1103, signal charges are accumulated in the first charge accumulation region (SN) 1102 and the second charge accumulation region (FD) 1104, and the potentials of the first charge accumulation region (SN) 1102 and the second charge accumulation region (FD) 1104 temporarily decrease, but then the charge discharge transistor 1108 overflows and discharges the signal charges. In (5-2) of FIG. 4B, the pixel signal corresponding to bright light is output from the selection transistor 1107. Therefore, the potential of the first charge accumulation region (SN) 1102 can be controlled between the threshold of the transfer transistor 1103 and the threshold of the charge discharge transistor 1108.

Next, at time t16, the drive signal TX reaches a high potential level, and the transfer transistor 1103 enters a conductive state. At this time, as illustrated in (6) of FIG. 4B, the potential barrier P1 corresponding to the transfer transistor 1103 is lowered, and the potential barriers P3 and P4 corresponding to the first charge accumulation region (SN) 1102 and the second charge accumulation region (FD) 1104, respectively, are higher than the potential barrier P1. The transfer transistor 1103 distributes the signal charge to both the first charge accumulation region (SN) 1102 and the second charge accumulation region (FD) 1104, and reads the signal potential as a D-phase pixel signal in the column processing section 13 via the source follower circuit. In general, in the overflow state of the transfer transistor 1103, it is difficult to read the signal charges remaining in the first charge accumulation region (SN) 1102, and the signal charges are affected in a form of afterimage or transfer failure. However, in the first embodiment of the present disclosure, since the transfer transistor 1103 is brought into a conductive state and read out, it is possible to read out all signal charges without these influences.

Next, at time t17, the drive signal RST reaches a high potential level, and the reset transistor 1105 enters a conductive state. Furthermore, by setting the VC voltage generated by the voltage generation circuit 1109 back to VC1, the first charge accumulation region (SN) 1102 and the second charge accumulation region (FD) 1104 are reset to the reset power supply voltage VRST. At this time, as illustrated in (7) of FIG. 4C, the potential barrier P2 corresponding to the reset transistor 1105 is lowered, and the potential barriers P3 and P4 corresponding to the first charge accumulation region (SN) 1102 and the second charge accumulation region (FD) 1104, respectively, are higher than the potential barriers P1 and P2. Note that the potential barriers P3 and P4 are lower than a potential barrier P5 corresponding to the charge discharge transistor 1108 in the non-conductive state.

Finally, at time t18, the drive signal RST reaches a low potential level, and the reset transistor 1105 enters a non-conductive state. At this time, as illustrated in (8) of FIG. 4C, the potential barrier P2 corresponding to the reset transistor 1105 returns to the original height and becomes higher than the potential barriers P3 and P4. At this time, the reference level at the time of reset is read as a P-phase pixel signal by the column processing section 13 via the source follower circuit.

In the first embodiment of the present disclosure, the state at the signal reading time t16 and the states of the first charge accumulation region (SN) 1102 and the second charge accumulation region (FD) 1104 at the reference level reading time t18 are the same in the settings of the transfer transistor 1103, the reset transistor 1105, and the charge discharge transistor 1108, but are different in the state of the voltage generation circuit 1109. Of course, it is possible to perform driving in which the states of the voltage generation circuit 1109 at t16 and t18 are the same, but this is omitted because the driving becomes complicated.

In the states at t16 and t18, the operation of the voltage generation circuit 1109 operates the first charge accumulation region (SN) 1102 and the second charge accumulation region (FD) 1104 in a floating state, and thus does not affect the charge amount in the first charge accumulation region (SN) 1102 and the second charge accumulation region (FD) 1104. The read reference signal level is offset from the original black level by ΔV={C_FD/(C_SN+C_FD)}*(VC1−VC2). This can be corrected in the light detection device 1 or by signal processing after output.

### Effects Produced by First Embodiment

As described above, according to the first embodiment, an operation is set such that a potential difference is applied between the first charge accumulation region (SN) 1102 and the second charge accumulation region (FD) 1104 so that a signal charge moves from the first charge accumulation region (SN) 1102 to the second charge accumulation region (FD) 1104, and the signal charge overflows the transfer transistor 1103 and moves to the second charge accumulation region (FD) 1104. Therefore, the applied voltage of the photoelectric conversion film 1101 during the accumulation period of the signal charges can be stabilized and reduced, and the pixel characteristics such as dark current can be improved as compared with the conventional circuit. In addition, since the signal charge amount (saturation amount) accumulated by the potential difference applied between the first charge accumulation region (SN) 1102 and the second charge accumulation region (FD) 1104 can be increased, the problem of the conventional overflow operation reading can be improved without increasing the accumulation capacity of the first charge accumulation region (SN) 1102.

Furthermore, according to the first embodiment, when the node potential of the second charge accumulation region (FD) 1104 reaches a specific potential, the overflow operation can be performed to discharge the signal charge. Therefore, the node potential of the first charge accumulation region (SN) 1102 can be controlled between the overflow voltage of the transfer transistor 1103 and the overflow voltage of the charge discharge transistor 1108, whereby the voltage applied to the photoelectric conversion film 1101 can be controlled without greatly changing.

Furthermore, regarding the accumulated charges, the charge Q=C_FD*(VC2−VC1) boosted by the voltage generation circuit 1109 can be accumulated in the second charge accumulation region (FD) 1104. Conventionally, since the operation is limited by the voltage applied to the photoelectric conversion film 1101 and the applied voltage cannot be increased, the charge amount that can be accumulated is limited. In the first embodiment of the present disclosure, by increasing the difference (VC2−VC1), it is possible to increase the accumulated charge amount without increasing the applied voltage of the photoelectric conversion film 1101. Note that, in the first embodiment, an example in which the voltage generation circuit 1109 is connected only to the second charge accumulation region (FD) 1104 has been described, but the voltage generation circuit 1109 may be connected to the first charge accumulation region (SN) 1102. Furthermore, the voltage generation circuit 1109 may be connected to both the first charge accumulation region (SN) 1102 and the second charge accumulation region (FD) 1104.

### Second Embodiment

FIG. 5 is an example of a circuit configuration diagram of a pixel 110A according to a second embodiment of the present disclosure. In FIG. 5, the same components as those in FIG. 2 described above are denoted by the same reference signs, and detailed description thereof is omitted.

In the second embodiment of the present disclosure, a shared transistor 1110 in which the reset transistor 1105 and the charge discharge transistor 1108 are shared is included. The shared transistor 1110 is an N-channel MOS transistor provided between a reset power supply line L3 that supplies a reset power supply voltage VRST and the second charge accumulation region (FD) 1104.

The voltage of a drive signal OFRST is applied to the gate electrode of the shared transistor 1110. When the drive signal OFRST reaches a high potential level, the shared transistor 1110 enters a conductive state. As a result, the potentials of the first charge accumulation region (SN) 1102 and the second charge accumulation region (FD) 1104 are reset to the reset power supply voltage VRST. Furthermore, the shared transistor 1110 discharges the signal charges remaining in the first charge accumulation region (SN) 1102 to the reset power supply line L3.

One electrode of the first charge accumulation region (SN) 1102 is connected to the other end of the photoelectric conversion film 1101 and the drain electrode of the transfer transistor 1103, and the other electrode is connected to the voltage generation circuit 1109.

One electrode of the second charge accumulation region (FD) 1104 is grounded (GND), and the other electrode is connected to each of the drain electrode of the transfer transistor 1103, the source electrode of the shared transistor 1110, and the gate electrode of the amplification transistor 1106.

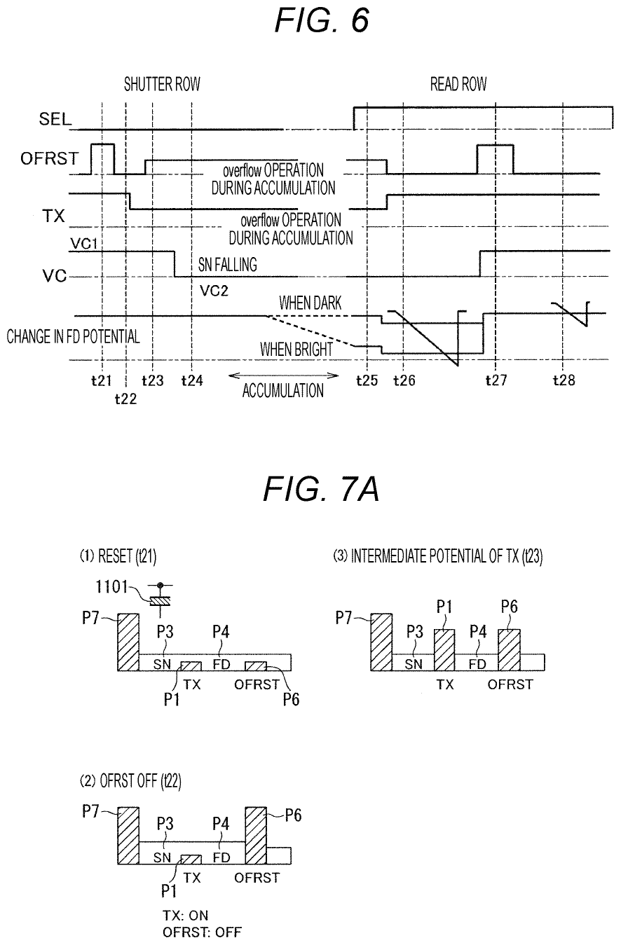

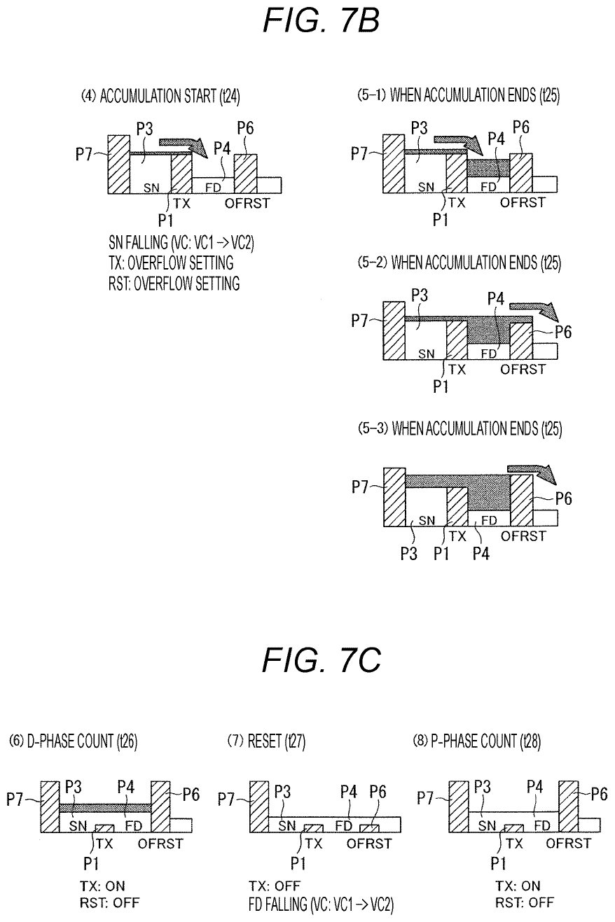

FIG. 6 is a timing chart depicting an example of the operation of the pixel in the pixel array section of the light detection device according to the second embodiment of the present disclosure, and specifically, is a timing chart depicting an example of processing related to exposure (light reception) by each pixel 110A. In the drawing, timing charts of the drive signals SEL, OFRST, TX, and VC are illustrated. FIGS. 7A to 7C illustrate potential diagrams at each time in the timing chart of FIG. 6.

First, at time t21, the drive signals OFRST and TX reach a high potential level, and the shared transistor 1110 and the transfer transistor 1103 enter a conductive state. Furthermore, by setting the VC voltage generated by the voltage generation circuit 1109 to VC1, the first charge accumulation region (SN) 1102 and the second charge accumulation region (FD) 1104 are reset to the reset power supply voltage VRST. At this time, as illustrated in (1) of FIG. 7A, a potential barrier P1 corresponding to the transfer transistor 1103 and a potential barrier P6 corresponding to the shared transistor 1110 are lowered, and potential barriers P3 and P4 corresponding to the first charge accumulation region (SN) 1102 and the second charge accumulation region (FD) 1104, respectively, are higher than the potential barriers P1 and P6. Note that the potential barriers P3 and P4 are lower than a potential barrier P7 on the left side in FIG. 7A of the first charge accumulation region (SN) 1102.

Next, at time t22, the drive signal OFRST reaches a low potential level, that is, the gate voltage of the shared transistor 1110 is less than the gate-source threshold voltage, and the shared transistor 1110 enters a non-conductive state. At this time, as illustrated in (2) of FIG. 7A, the potential barrier P6 corresponding to the shared transistor 1110 returns to the original height and becomes higher than the potential barriers P3 and P4.

Next, at time t23, the drive signal TX is at a low potential level, that is, the gate voltage of the transfer transistor 1103 becomes less than the gate-source threshold voltage, and the transfer transistor 1103 enters a non-conductive state. At this time, as illustrated in (3) of FIG. 7A, the gate voltage of the transfer transistor 1103 is set to an intermediate voltage around the gate-source threshold voltage. Furthermore, the gate voltage of the shared transistor 1110 is set to an intermediate voltage around the gate-source threshold voltage. As a result, the potential barrier P6 corresponding to the shared transistor 1110 becomes lower than the non-conductive state.

Next, at time t24, the VC voltage generated by the voltage generation circuit 1109 is set to VC2 lower than VC1. At this time, as illustrated in (4) of FIG. 7B, the voltage applied to the first charge accumulation region (SN) 1102 is lowered, and the potential barrier P4 corresponding to the first charge accumulation region (SN) 1102 becomes lower than the potential barrier P4 corresponding to the second charge accumulation region (FD) 1104. As a result, the signal charge generated in the photoelectric conversion film 1101 overflows the first charge accumulation region (SN) 1102 and the transfer transistor 1103 and is accumulated in the second charge accumulation region (FD) 1104.

Next, at time t25, the drive signal SEL reaches a high potential level, and the selection transistor 1107 enters a conductive state. At this time, as illustrated in (5-1) of FIG. 7B, during the accumulation period, the VC voltage is held at VC2, the gate voltage of the transfer transistor 1103 is also held at the intermediate voltage, the signal charge is accumulated in the second charge accumulation region (FD) 1104, and the potential of the first charge accumulation region (SN) 1102 is kept constant. In (5-1) of FIG. 7B, a pixel signal corresponding to dark light is output from the selection transistor 1107.

On the other hand, as illustrated in (5-2) of FIG. 7B, in a case where the threshold of the shared transistor 1110 is equal to or less than the threshold of the transfer transistor 1103, the potential of the first charge accumulation region (SN) 1102 does not change, and the extra charges overflow the shared transistor 1110 and are discharged. In (5-3) of FIG. 7B, in a case where the threshold of the shared transistor 1110 is higher than that of the transfer transistor 1103, when the potential of the second charge accumulation region (FD) 1104 exceeds the intermediate voltage of the transfer transistor 1103, signal charges are accumulated in the first charge accumulation region (SN) 1102 and the second charge accumulation region (FD) 1104, and the potentials of the first charge accumulation region (SN) 1102 and the second charge accumulation region (FD) 1104 temporarily decrease, but the shared transistor 1110 then overflows and discharges the signal charges. In (5-3) of FIG. 7B, the pixel signal corresponding to bright light is output from the selection transistor 1107. Therefore, the potential of the first charge accumulation region (SN) 1102 can be controlled within a range between the threshold of the transfer transistor 1103 and the threshold of the shared transistor 1110.

Next, at time t26, the drive signal TX reaches a high potential level, and the transfer transistor 1103 enters a conductive state. At this time, as illustrated in (6) of FIG. 7C, the potential barrier P1 corresponding to the transfer transistor 1103 is lowered, and the potential barriers P3 and P4 corresponding to the first charge accumulation region (SN) 1102 and the second charge accumulation region (FD) 1104, respectively, are higher than the potential barrier P1. The transfer transistor 1103 distributes the signal charge to both the first charge accumulation region (SN) 1102 and the second charge accumulation region (FD) 1104, and reads the signal potential as a D-phase pixel signal in the column processing section 13 via the source follower circuit. In general, in the overflow state of the transfer transistor 1103, it is difficult to read the signal charges remaining in the first charge accumulation region (SN) 1102, and the signal charges are affected in a form of afterimage or transfer failure. However, in the second embodiment of the present disclosure, since the transfer transistor 1103 is brought into a conductive state and read out, it is possible to read out all signal charges without these influences.

Next, at time t27, the drive signal OFRST reaches a high potential level, and the shared transistor 1110 enters a conductive state. Furthermore, by setting the VC voltage generated by the voltage generation circuit 1109 back to VC1, the first charge accumulation region (SN) 1102 and the second charge accumulation region (FD) 1104 are reset to the reset power supply voltage VRST. At this time, as illustrated in (7) of FIG. 7C, the potential barrier P6 corresponding to the shared transistor 1110 is lowered, and the potential barriers P3 and P4 corresponding to the first charge accumulation region (SN) 1102 and the second charge accumulation region (FD) 1104, respectively, are higher than the potential barriers P1 and P6.

Finally, at time t28, the drive signal OFRST reaches a low potential level, and the shared transistor 1110 enters a non-conductive state. At this time, as illustrated in (8) of FIG. 7C, the potential barrier P6 corresponding to the shared transistor 1110 returns to the original height and becomes higher than the potential barriers P3 and P4. At this time, the reference level at the time of reset is read as a P-phase pixel signal by the column processing section 13 via the source follower circuit.

In the second embodiment of the present disclosure, the state at the signal reading time t26 and the states of the first charge accumulation region (SN) 1102 and the second charge accumulation region (FD) 1104 at the reference level reading time t28 are the same in the settings of the transfer transistor 1103, and the shared transistor 1110 but are different in the state of the voltage generation circuit 1109. Of course, it is possible to perform driving in which the states of the voltage generation circuit 1109 at t26 and t28 are the same, but this is omitted because the driving becomes complicated.

In the states at t16 and t18, the operation of the voltage generation circuit 1109 operates the first charge accumulation region (SN) 1102 and the second charge accumulation region (FD) 1104 in a floating state, and thus does not affect the charge amount in the first charge accumulation region (SN) 1102 and the second charge accumulation region (FD) 1104. The read reference signal level is offset from the original black level by ΔV={C_FD/(C_SN+C_FD)}*(VC1−VC2). This can be corrected in the light detection device 1 or by signal processing after output.

### Effects Produced by Second Embodiment

As described above, according to the second embodiment, the similar effects as those of the first embodiment can be obtained, and the number of elements can be reduced by using the shared transistor 1110 as the charge discharge transistor and the reset transistor.

### Third Embodiment

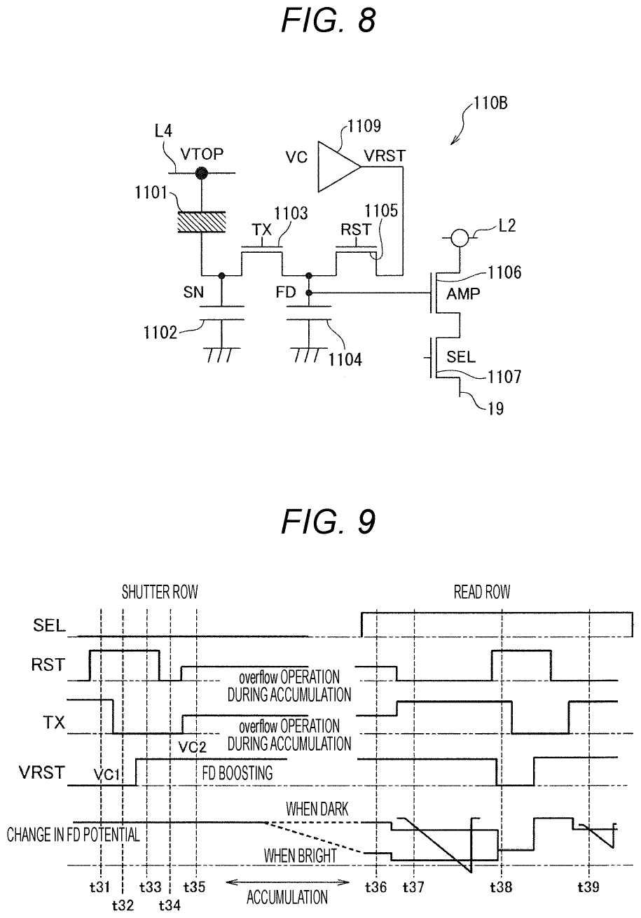

FIG. 8 is an example of a circuit configuration diagram of a pixel 110B according to a third embodiment of the present disclosure. In FIG. 8, the same components as those in FIG. 2 described above are denoted by the same reference signs, and detailed description thereof is omitted.

In the third embodiment of the present disclosure, the reset transistor 1105 performs the function of the charge discharge transistor. Furthermore, the voltage generation circuit 1109 is connected to a drain electrode of the reset transistor 1105.

One electrode of the first charge accumulation region (SN) 1102 is connected to the other end of the photoelectric conversion film 1101 and the drain electrode of the transfer transistor 1103, and the other electrode is grounded (GND).

One electrode of the second charge accumulation region (FD) 1104 is grounded (GND), and the other electrode is connected to each of the drain electrode of the transfer transistor 1103, the source electrode of the reset transistor 1105, and the gate electrode of the amplification transistor 1106.

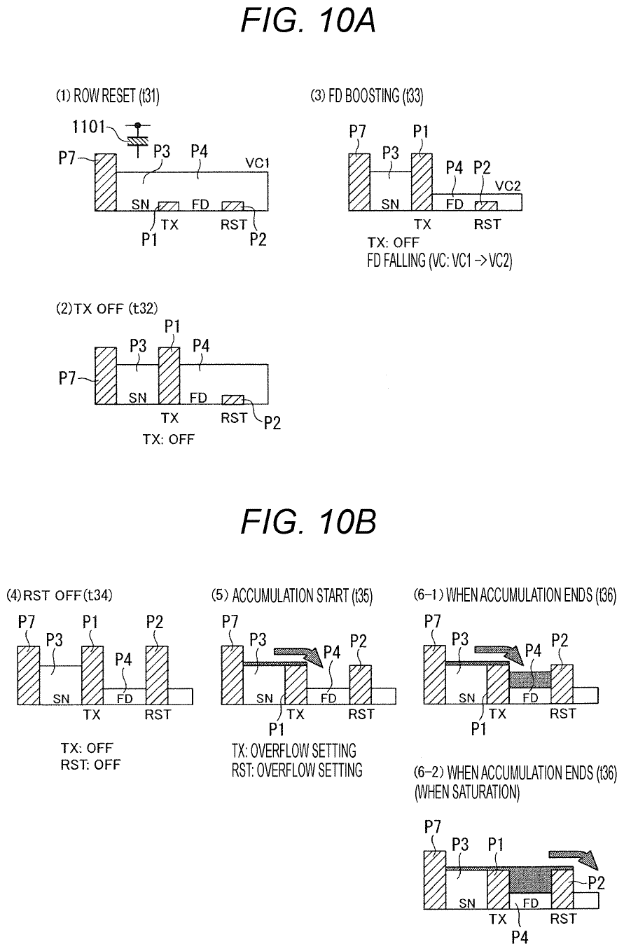

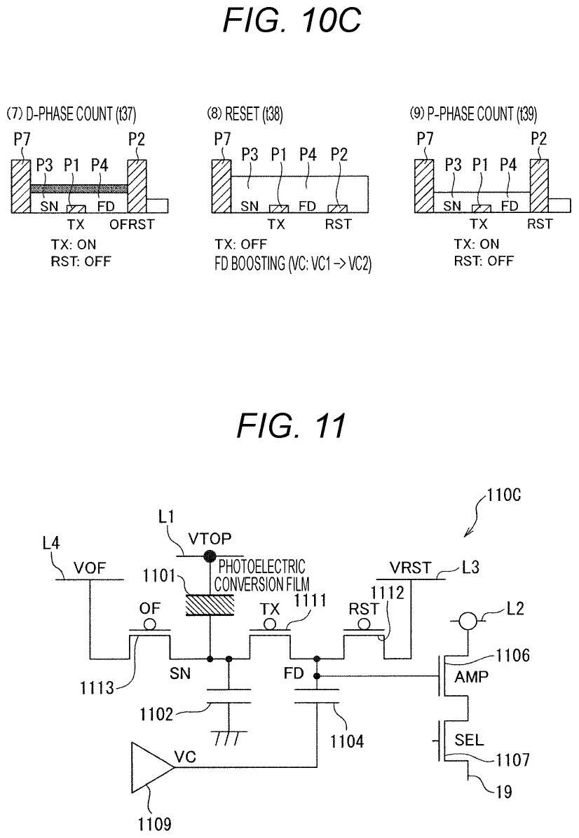

FIG. 9 is a timing chart depicting an example of the operation of the pixel in the pixel array section of the light detection device according to the third embodiment of the present disclosure, and specifically, is a timing chart depicting an example of processing related to exposure (light reception) by each pixel 110B. In the drawing, timing charts of the drive signals SEL, RST, TX, and VRST are illustrated. FIGS. 10A to 10C illustrate potential diagrams at each time in the timing chart of FIG. 9.

First, at time t31, the drive signals RST and TX reaches a high potential level, and the reset transistor 1105 and the transfer transistor 1103 enter the conductive state. Furthermore, by setting the VC voltage generated by the voltage generation circuit 1109 to VC1, the first charge accumulation region (SN) 1102 and the second charge accumulation region (FD) 1104 are reset to VC1. At this time, as illustrated in (1) of FIG. 10A, a potential barrier P1 corresponding to the transfer transistor 1103 and a potential barrier P2 corresponding to the reset transistor 1105 are lowered, and potential barriers P3 and P4 corresponding to the first charge accumulation region (SN) 1102 and the second charge accumulation region (FD) 1104, respectively, are higher than the potential barriers P1 and P2. Note that the potential barriers P3 and P4 are lower than a potential barrier P7 on the left side in FIG. 10A of the first charge accumulation region (SN) 1102.

Next, at time t32, the drive signal TX is at a low potential level, that is, the gate voltage of the transfer transistor 1103 becomes less than the gate-source threshold voltage, and the transfer transistor 1103 enters a non-conductive state. At this time, as illustrated in (2) of FIG. 10A, the potential barrier P1 corresponding to the transfer transistor 1103 returns to the original height and becomes higher than the potential barriers P3 and P4.

Next, at time t33, the reset power supply voltage VRST is set to VC2 higher than VC1. At this time, as illustrated in (3) of FIG. 10A, the voltage applied to the second charge accumulation region (FD) 1104 is boosted, and the potential barrier P4 corresponding to the second charge accumulation region (FD) 1104 becomes lower than the potential barrier P3 corresponding to the first charge accumulation region (SN) 1102.

Next, at time t34, the drive signal RST is at a low potential level, that is, the gate voltage of the reset transistor 1105 becomes less than the gate-source threshold voltage, and the reset transistor 1105 enters a non-conductive state. At this time, as illustrated in (4) of FIG. 10B, the potential barrier P2 corresponding to the reset transistor 1105 returns to the original height and becomes higher than the potential barriers P3 and P4.

Next, at time t35, the gate voltage of the transfer transistor 1103 is set to an intermediate voltage around the gate-source threshold voltage. Furthermore, the gate voltage of the reset transistor 1105 is set to an intermediate voltage around the gate-source threshold voltage. As a result, as illustrated in (5) of FIG. 10B, the potential barriers P1 and P2 become lower than the non-conductive state.

Next, at time t36, the drive signal SEL reaches a high potential level, and the selection transistor 1107 enters a conductive state. At this time, as illustrated in (6-1) of FIG. 10B, during the accumulation period, the VC voltage is held at VC2, the gate voltage of each of the transfer transistor 1103 and the reset transistor 1105 is also held at the intermediate voltage, the signal charge is accumulated in the second charge accumulation region (FD) 1104, and the potential of the first charge accumulation region (SN) 1102 is kept constant. In (6-1) of FIG. 10B, a pixel signal corresponding to dark light is output from the selection transistor 1107.

On the other hand, as illustrated in (6-2) of FIG. 10B, when the potential of the second charge accumulation region (FD) 1104 exceeds the intermediate voltage of the reset transistor 1105, the signal charge overflows from the reset transistor 1105 and is discharged. When the overflow voltage of the transfer transistor 1103 is larger than the overflow voltage of the reset transistor 1105, the potential of the first charge accumulation region (SN) 1102 is determined only by the threshold of the transfer transistor 1103, and thus is kept constant from the time of charge accumulation to the time of saturation. Even in a case where the overflow voltage of the transfer transistor 1103 is smaller than the overflow voltage of the reset transistor 1105, if the overflow voltage of the transfer transistor 1103 and the overflow voltage of the reset transistor 1105 are close to each other, the potential of the first charge accumulation region (SN) 1102 does not greatly fluctuate, and can be controlled within a range between the threshold of the transfer transistor 1103 and the threshold of the reset transistor 1105.

Next, at time t37, the drive signal TX reaches a high potential level, and the transfer transistor 1103 enters a conductive state. At this time, as illustrated in (7) of FIG. 10C, the potential barrier P1 corresponding to the transfer transistor 1103 is lowered, and the potential barriers P3 and P4 corresponding to the first charge accumulation region (SN) 1102 and the second charge accumulation region (FD) 1104, respectively, are higher than the potential barrier P1. The transfer transistor 1103 distributes the signal charge to both the first charge accumulation region (SN) 1102 and the second charge accumulation region (FD) 1104, and reads the signal potential as a D-phase pixel signal in the column processing section 13 via the source follower circuit. In general, in the overflow state of the transfer transistor 1103, it is difficult to read the signal charges remaining in the first charge accumulation region (SN) 1102, and the signal charges are affected in a form of afterimage or transfer failure. However, in the third embodiment of the present disclosure, since the transfer transistor 1103 is brought into a conductive state and read out, it is possible to read out all signal charges without these influences.

Next, at time t38, the drive signal RST reaches a high potential level, and the reset transistor 1105 enters a conductive state. Furthermore, by setting the VC voltage generated by the voltage generation circuit 1109 back to VC1, the first charge accumulation region (SN) 1102 and the second charge accumulation region (FD) 1104 are reset to VC1. At this time, as illustrated in (8) of FIG. 10C, the potential barrier P2 corresponding to the reset transistor 1105 is lowered, and the potential barriers P3 and P4 corresponding to the first charge accumulation region (SN) 1102 and the second charge accumulation region (FD) 1104, respectively, are higher than the potential barriers P1 and P2.

Finally, at time t39, the drive signal RST reaches a low potential level, and the reset transistor 1105 enters a non-conductive state. At this time, as illustrated in (9) of FIG. 10C, the potential barrier P2 corresponding to the reset transistor 1105 returns to the original height and becomes higher than the potential barriers P3 and P4. Finally, by bringing the transfer transistor 1103 into a conductive state, a black level signal in which no signal charge is accumulated can be read out.

### Effects Produced by Third Embodiment

As described above, according to the third embodiment, similar to the second embodiment described above, the number of elements is reduced, and the similar effects as those of the first embodiment described above can be obtained.

### Fourth Embodiment

FIG. 11 is an example of a circuit configuration diagram of a pixel 110C according to the fourth embodiment of the present disclosure. In FIG. 11, the same components as those in FIG. 2 described above are denoted by the same reference signs, and detailed description thereof is omitted.

In the first to third embodiments described above, since the signal charges are electrons, N-channel MOS transistors are used. In a case where the signal charges are holes, a similar overflow operation can be performed using P-channel MOS transistors.

The fourth embodiment of the present disclosure includes a transfer transistor 1111, a reset transistor 1112, and a charge discharge transistor 1113. The transfer transistor 1111, the reset transistor 1112, and the charge discharge transistor 1113 are P-channel MOS transistors having a polarity opposite to that of the N-channel MOS transistor.

The transfer transistor 1111 is provided between the photoelectric conversion film 1101 and the second charge accumulation region (FD) 1104. The reset transistor 1112 is provided between the reset power supply line L3 that supplies the reset power supply voltage VRST and the second charge accumulation region (FD) 1104. The charge discharge transistor 1113 is provided between the power supply line L4 that supplies the power supply voltage VOF and the first charge accumulation region (SN) 1102.

### Effects Produced by Fourth Embodiment

As described above, according to the fourth embodiment, the transfer transistor 1111, the reset transistor 1112, and the charge discharge transistor 1113 are changed to P-channel MOS transistors, and overflow operation is performed, whereby the potential of the first charge accumulation region (SN) 1102 can be kept substantially constant.

### Fifth Embodiment

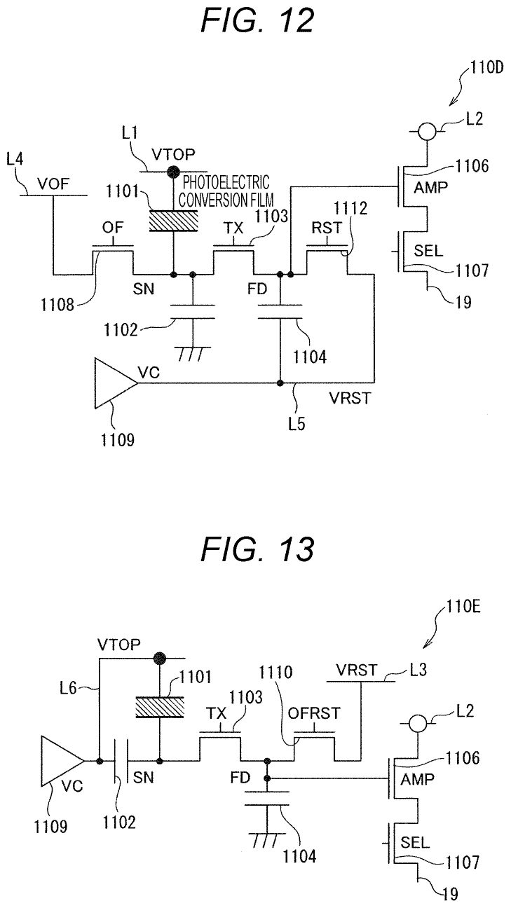

FIG. 12 is an example of a circuit configuration diagram of a pixel 110D according to a fifth embodiment of the present disclosure. In FIG. 12, the same components as those in FIG. 2 described above are denoted by the same reference signs, and detailed description thereof is omitted.

The fifth embodiment of the present disclosure is an example in which the power supply line of the voltage generation circuit 1109 and the reset power supply line L3 are used in common. One electrode of the second charge accumulation region (FD) 1104 is connected to the voltage generation circuit 1109 via a power supply line L5, and the other electrode is connected to each of the drain electrode of the transfer transistor 1103, the source electrode of the reset transistor 1105, and the gate electrode of the amplification transistor 1106. The drain electrode of the reset transistor 1105 is connected to the voltage generation circuit 1109 via the power supply line L5.

### Effects Produced by Fifth Embodiment

As described above, according to the fifth embodiment, the power supply line of the voltage generation circuit 1109 and the reset power supply line can be used in common by one power supply line L5 in order to reduce the number of in-pixel wirings in the fine pixel.

### Sixth Embodiment

FIG. 13 is an example of a circuit configuration diagram of a pixel 110E according to a sixth embodiment of the present disclosure. In FIG. 13, the same portions as those in FIG. 5 above are denoted by the same reference numerals, and a detailed description thereof is omitted.

The sixth embodiment of the present disclosure is an example in which the power supply line of the voltage generation circuit 1109 and one power supply line L1 of the photoelectric conversion film 1101 are used in common. One end of the photoelectric conversion film 1101 is connected to a voltage generation circuit 11109 via a power supply line L6 that supplies a power supply voltage VTOP. One electrode of the first charge accumulation region (SN) 1102 is connected to the other end of the photoelectric conversion film 1101 and the drain electrode of the transfer transistor 1103, and the other electrode is connected to the voltage generation circuit 11109 via the power supply line L6.

### Effects Produced by Sixth Embodiment

As described above, according to the sixth embodiment, the power supply line of the voltage generation circuit 1109 and one power supply line of the photoelectric conversion film 1101 can be used in common by one power supply line L6 in order to reduce the number of in-pixel wirings in the fine pixel.

### Seventh Embodiment

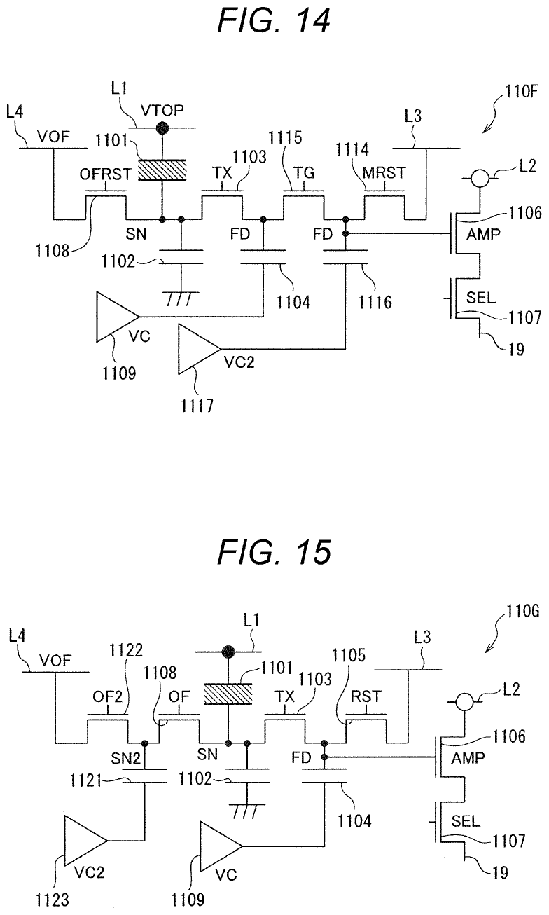

FIG. 14 is an example of a circuit configuration diagram of a pixel 110F according to a seventh embodiment of the present disclosure. In FIG. 14, the same components as those in FIG. 2 described above are denoted by the same reference signs, and detailed description thereof is omitted.

The seventh embodiment of the present disclosure configures a global shutter circuit. That is, in the seventh embodiment of the present disclosure, a reset transistor 1114, an additional transfer transistor 1115, a third charge accumulation region (GM) 1116, and a voltage generation circuit 1117 are included.

The additional transfer transistor 1115 is an N-channel MOS transistor provided between the source electrode of the transfer transistor 1103 and the second charge accumulation region (FD) 1104, and the reset transistor 1114 and the third charge accumulation region (GM) 1116. The voltage of a drive signal TG is applied to a gate electrode of the additional transfer transistor 1115. That is, when the drive signal TG exceeds a high potential level, that is, a gate-source threshold voltage, the additional transfer transistor 1115 enters a conductive state, and the signal charge accumulated in the second charge accumulation region (FD) 1104 is transferred to the third charge accumulation region (GM) 1116 via the additional transfer transistor 1115.

The third charge accumulation region (GM) 1116 is a floating diffusion region capable of holding a predetermined charge amount, and accumulates signal charges transferred by the additional transfer transistor 1115. One electrode of the third charge accumulation region (GM) 1116 is connected to the voltage generation circuit 1117, and the other electrode is connected to each of the drain electrode of the additional transfer transistor 1115, the source electrode of the reset transistor 1114, and the gate electrode of the amplification transistor 1106. The signal charge accumulated in the third charge accumulation region (GM) 1116 is read out by charge-voltage conversion into a voltage signal.

The reset transistor 1114 is an N-channel MOS transistor provided between a reset power supply line L3 that supplies a reset power supply voltage VRST and the third charge accumulation region (GM) 1116. The voltage of a drive signal MRST is applied to a gate electrode of the reset transistor 1114. When the drive signal MRST reaches a high potential level, the reset transistor 1114 enters a conductive state. As a result, the potentials of the first charge accumulation region (SN) 1102, the second charge accumulation region (FD) 1104, and the third charge accumulation region (GM) 1116 are reset to the reset power supply voltage VRST.

Note that the additional transfer transistor 1115 may be connected to the first charge accumulation region (SN) 1102, or may be connected in parallel with the transfer transistor 1103.

### Effects Produced by Seventh Embodiment

As described above, according to the seventh embodiment, by accumulating a part of the signal charges accumulated in the first charge accumulation region (SN) 1102 in the third charge accumulation region (GM) 1116, the signal charges accumulated in the third charge accumulation region (GM) 1116 can be read even during charge accumulation in the second charge accumulation region (FD) 1104, and can be used at the time of global shutter operation.

### Eighth Embodiment

FIG. 15 is an example of a circuit configuration diagram of a pixel 110G according to an eighth embodiment of the present disclosure. In FIG. 15, the same components as those in FIG. 2 described above are denoted by the same reference signs, and detailed description thereof is omitted.

The eighth embodiment of the present disclosure configures a conversion efficiency variable circuit. That is, the eighth embodiment of the present disclosure includes an additional capacitance section (SN2) 1121, a switching transistor 1122, and a voltage generation circuit 1123.

The switching transistor 1122 is an N-channel MOS transistor provided between the power supply line L4 that supplies the power supply voltage VOF, the charge discharge transistor 1108, and the additional capacitance section (SN2) 1121. The voltage of a drive signal OF2 is applied to the gate electrode of the switching transistor 1122. When the drive signal OF2 reaches a high potential level, the switching transistor 1122 enters a conductive state. As a result, the first charge accumulation region (SN) 1102 and the additional capacitance section (SN2) 1121 can be electrically coupled.

The additional capacitance section (SN2) 1121 provides an additional capacitance by coupling with the first charge accumulation region (SN) 1102 according to a predetermined operating condition. One electrode of the additional capacitance section (SN2) 1121 is connected to the voltage generation circuit 1123, and the other electrode is connected to the charge discharge transistor 1108 and the switching transistor 1122.

### Effects Produced by Eighth Embodiment

As described above, according to the eighth embodiment, in a case where the switching transistor 1122 is always turned on, and the operation of the eighth embodiment of the present disclosure is performed by a combination of the charge discharge transistor 1108 and the transfer transistor 1103, the conversion efficiency of this circuit is q/(Csn+Cfd). Furthermore, next, when the charge discharge transistor 1108 is always turned on and the operation of the eighth embodiment of the present disclosure is performed by a combination of the switching transistor 1122 and the transfer transistor 1103, the conversion efficiency of the additional capacitance section (SN2) 1121 contributes to q/(Csn+Csn2+Cfd), and the conversion efficiency can be changed.

### Ninth Embodiment

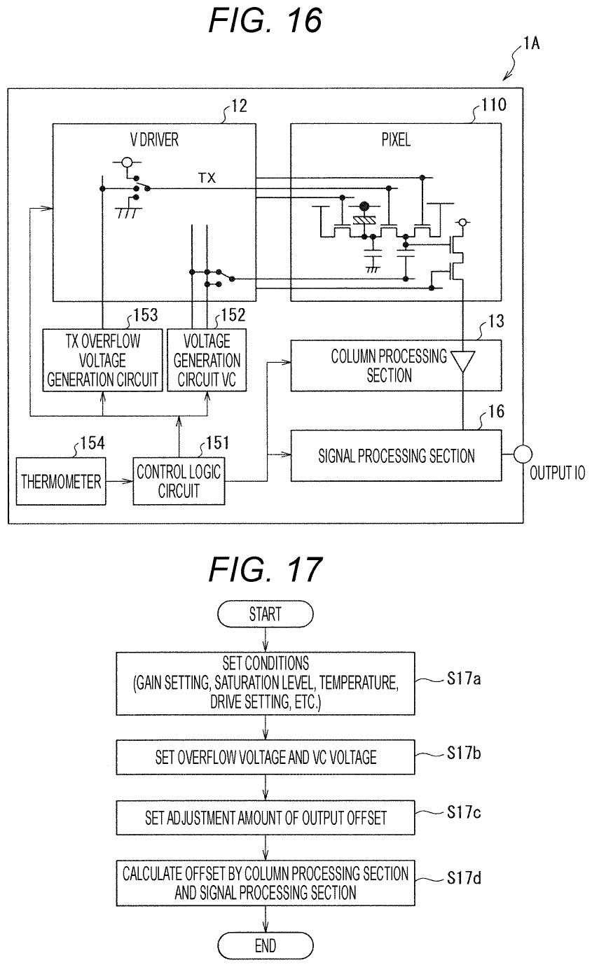

FIG. 16 is a block diagram depicting an example of a schematic configuration of a light detection device 1A according to a ninth embodiment of the present disclosure. In FIG. 16, the same components as those in FIG. 1 described above are denoted by the same reference signs, and detailed description thereof is omitted.

In the ninth embodiment of the present disclosure, the system control section 15 includes a control logic circuit 151, a voltage generation circuit 152, an overflow voltage generation circuit 153, and a thermometer 154. The control logic circuit 151 controls the voltage generation circuit 152 and the overflow voltage generation circuit 153 and controls the column processing section 13 and the signal processing section 16 on the basis of condition settings such as a temperature in the light detection device 1A measured by the thermometer 154, a gain setting, a saturation level, and a state of a power supply voltage. The voltage generation circuit 152 supplies the VC voltage to the first charge accumulation region (SN) 1102 or the second charge accumulation region (FD) 1104 via the vertical drive section 12 under the control of the control logic circuit 151.

The overflow voltage generation circuit 153 generates an overflow voltage to be applied to the gate electrode of the transfer transistor 1103 via the vertical drive section 12 under the control of the control logic circuit 151.

Under the control of the control logic circuit 151, the column processing section 13 and the signal processing section 16 calculate an offset amount added to the pixel signal read from the pixel 110, and correct the pixel signal on the basis of the offset amount.

FIG. 17 is a flowchart illustrating a control processing procedure of the control logic circuit 151 according to the ninth embodiment of the present disclosure.

First, the control logic circuit 151 sets conditions such as a temperature in the light detection device 1A measured by the thermometer 154, a gain setting, a saturation level, and a state of a power supply voltage (step ST17a). Subsequently, the control logic circuit 151 controls the voltage generation circuit 152 and the overflow voltage generation circuit 153 on the basis of the condition setting, and calculates a VC voltage to be applied to the first charge accumulation region (SN) 1102 or the second charge accumulation region (FD) 1104 and an overflow voltage to be applied to the gate electrode of the transfer transistor 1103 (step ST17b).

Subsequently, the control logic circuit 151 controls the column processing section 13 and the signal processing section 16 on the basis of the condition setting to calculate the offset amount added to the pixel signal output from the pixel 110 to be processed (step ST17c), and causes the column processing section 13 and the signal processing section 16 to execute correction of the pixel signal based on the offset amount (step ST17d).

As the reference signal level read from the pixel 110, an offset amount of ΔV={C_FD/(C_SN+C_FD)}*(VC1−VC2) is added from the original black level. Among them, (VC1−VC2) is determined by the temperature in the light detection device 1A measured by the thermometer 154, the gain setting, the saturation level, and the state of the power supply voltage.

### Effects Produced of Ninth Embodiment

As described above, according to the ninth embodiment, for example, the VC voltage to be applied to the first charge accumulation region (SN) 1102 or the second charge accumulation region (FD) 1104 and the overflow voltage to be applied to the gate electrode of the transfer transistor 1103 are calculated according to conditions such as temperature, a power supply voltage, a gain setting, and a drive setting, the offset amount to be added to the pixel signal read from the pixel 110 is further calculated according to the conditions, and the pixel signal is corrected on the basis of the offset amount, whereby the VC voltage to be applied to the first charge accumulation region (SN) 1102 or the second charge accumulation region (FD) 1104 that changes according to the set conditions, and the overflow voltage to be applied to the gate electrode of the transfer transistor 1103 can be variably set, and a more accurate pixel signal can be obtained.

### Other Embodiments

The present technology has been described as above according to the first to ninth embodiments, but it should not be understood that the description and drawings forming a part of this disclosure limit the present technology. It will be apparent to those skilled in the art that various alternative embodiments, examples, and operation techniques can be included in the present technology when understanding the spirit of the technical content disclosed in the first to ninth embodiments described above. Furthermore, the configurations disclosed in the first to ninth embodiments can be appropriately combined within a range in which no contradiction occurs. For example, configurations disclosed in a plurality of different embodiments may be combined, or configurations disclosed in a plurality of different modifications of the same embodiment may be combined.

### Application Example to Electronic Apparatus

The light detection device described above can be applied to various electronic apparatuses such as, for example, an imaging device such as a digital still camera and a digital video camera, a mobile phone with an imaging function, or other devices having an imaging function.

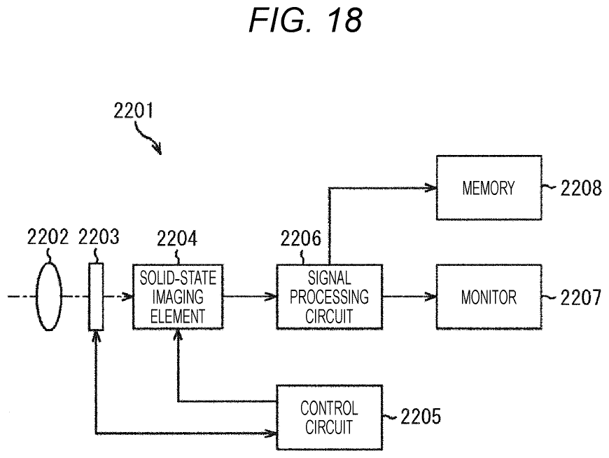

FIG. 18 is a block diagram illustrating a configuration example of the imaging device as the electronic apparatus to which the present technology is applied.

An imaging device 2201 illustrated in FIG. 18 includes an optical system 2202, a shutter device 2203, a solid-state imaging element 2204 as a light detection device, a control circuit 2205, a signal processing circuit 2206, a monitor 2207, and a memory 2208, and can capture a still image and a moving image.

The optical system 2202 includes one or a plurality of lenses, and guides light from a subject (incident light) to the solid-state imaging element 2204 to form an image on a light receiving surface of the solid-state imaging element 2204.

The shutter device 2203 arranged between the optical system 2202 and the solid-state imaging element 2204 controls a light irradiation period to the solid-state imaging element 2204 and a light shielding period according to control of the control circuit 2205.

The solid-state imaging element 2204 includes a package including the solid-state imaging element described above. The solid-state imaging element 2204 accumulates a signal charge for a certain period according to the light the image of which is formed as an image on the light receiving surface via the optical system 2202 and the shutter device 2203. The signal charges accumulated in the solid-state imaging element 2204 are transferred according to a drive signal (timing signal) supplied from the control circuit 2205.

The control circuit 2205 outputs the drive signal to control a transfer operation of the solid-state imaging element 2204 and a shutter operation of the shutter device 2203 to drive the solid-state imaging element 2204 and the shutter device 2203.

The signal processing circuit 2206 performs various types of signal processing on the signal charges output from the solid-state imaging element 2204. An image (image data) obtained by the signal processing circuit 2206 performing the signal processing is supplied to the monitor 2207 to be displayed or supplied to the memory 2208 to be stored (recorded).

Also in the imaging device 2201 configured as described above, the light detection device 1 can be applied instead of the solid-state imaging element 2204 described above.

### Application Example to Mobile Body

The technology according to the present disclosure (the present technology) can be applied to various products. For example, the technology of the present disclosure may be achieved in the form of a device to be mounted on a mobile object of any kind, such as an automobile, an electric vehicle, a hybrid electric vehicle, a motorcycle, a bicycle, a personal mobility, an airplane, a drone, a vessel, or a robot.

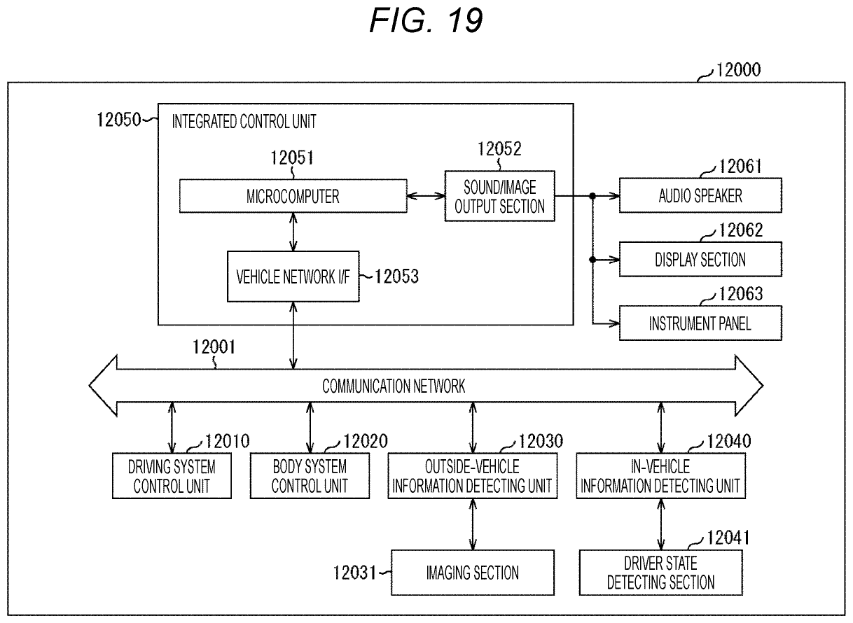

FIG. 19 is a block diagram depicting a schematic configuration example of a vehicle control system which is an example of a moving body control system to which the technology according to the present disclosure can be applied.

The vehicle control system 12000 includes a plurality of electronic control units connected to each other via a communication network 12001. In the example illustrated in FIG. 19, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 may output a control command to the body system control unit 12020 on the basis of the information about the outside of the vehicle obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 19, an audio speaker 12061, a display section 12062, and an instrument panel 12063 are illustrated as the output device. The display section 12062 may, for example, include at least one of an on-board display and a head-up display.

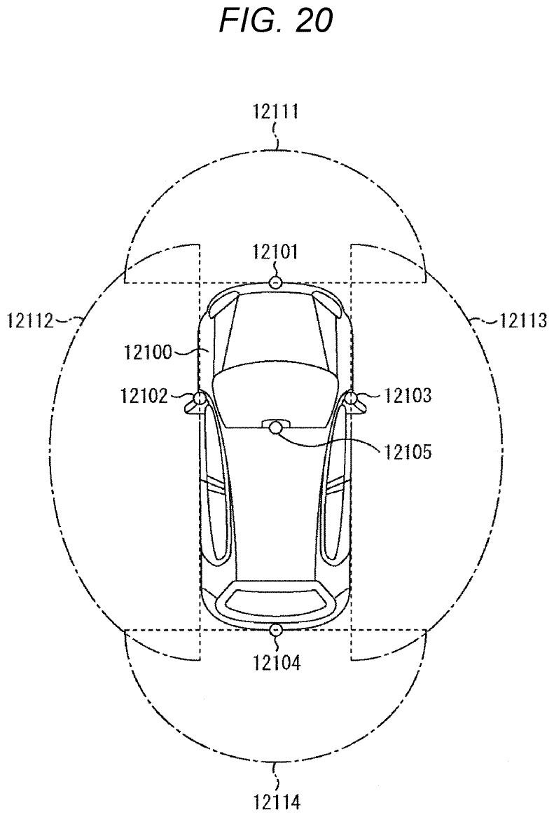

FIG. 20 is a diagram depicting an example of the installation position of the imaging section 12031.

In FIG. 20, a vehicle 12100 includes, as the imaging section 12031, imaging sections 12101, 12102, 12103, 12104, and 12105.

The imaging sections 12101, 12102, 12103, 12104, and 12105 are, for example, provided at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The images of the forward view acquired by the imaging sections 12101 and 12105 are mainly used to detect a preceding vehicle, a pedestrian, an obstacle, a traffic light, a traffic sign, a lane, or the like.

Note that FIG. 20 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

Note that the present disclosure can also have the following configurations.
(1)

A light detection device including:
a pixel array section in which a plurality of pixels is arranged in an array, in which
each of the plurality of pixels includes:
a photoelectric conversion film that generates a signal charge of an amount corresponding to light incident from an outside;
a first charge accumulation section that is connected to the photoelectric conversion film and receives and accumulates the signal charge;
a transfer transistor that is connected to the photoelectric conversion film and the first charge accumulation section and transfers the signal charge accumulated in the first charge accumulation section;
a second charge accumulation section that temporarily accumulates signal charges transferred by the transfer transistor; and
a potential difference generation section that generates a potential difference between the first charge accumulation section and the second charge accumulation section, and
a gate voltage of the transfer transistor is set to be switched to a first voltage to be turned on, a second voltage to be turned off and lower than the first voltage, and a third voltage between the first voltage and the second voltage, the third voltage causing the signal charge to overflow from the first charge accumulation section to the second charge accumulation section.
(2)

The light detection device according to (1), further including: a charge discharge transistor configured to discharge the signal charge.
(3)

The light detection device according to (2), in which the charge discharge transistor is connected to the first charge accumulation section.
(4)

The light detection device according to (2), in which the charge discharge transistor is connected to the second charge accumulation section.
(5)

The light detection device according to (1), further including: a reset transistor that resets potentials of the first charge accumulation section and the second charge accumulation section.
(6)

The light detection device according to (2), in which the charge discharge transistor is connected to the second charge accumulation section, and is also used in common with a reset transistor that resets potentials of the first charge accumulation section and the second charge accumulation section.
(7)

The light detection device according to (2), in which a gate voltage of the charge discharge transistor is higher than the third voltage set to a gate voltage of the transfer transistor by 1 V or less, and is set to be switched to the overflowing fourth voltage.
(8)

The light detection device according to (4), in which a gate voltage of the charge discharge transistor is higher than the third voltage set to a gate voltage of the transfer transistor, and is set to be switched to the overflowing fourth voltage.
(9)

The light detection device according to (2), in which in a case where the signal charge includes an electron, the transfer transistor and the charge discharge transistor include transistors of a first conductivity type.
(10)

The light detection device according to (9), in which in a case where the signal charge includes a hole, the transfer transistor and the charge discharge transistor include transistors of a second conductivity type having a polarity opposite to the first conductivity type.
(11)

The light detection device according to (1), in which the potential difference generation section is connected to at least one of the first charge accumulation section and the second charge accumulation section, and generates a potential difference between the first charge accumulation section and the second charge accumulation section.
(12)

The light detection device according to (1), in which the potential difference generation section is connected to both the first charge accumulation section and the second charge accumulation section, and generates a potential difference between the first charge accumulation section and the second charge accumulation section.
(13)

The light detection device according to (5), in which the potential difference generation section changes a drain voltage of the reset transistor at a drive timing.
(14)

The light detection device according to (1), in which the potential difference generation section changes a voltage to be applied to the photoelectric conversion film at a drive timing.
(15)

The light detection device according to (1), further including: an additional transfer transistor that is connected to the first charge accumulation section or the second charge accumulation section and transfers the signal charge accumulated in the first charge accumulation section or the second charge accumulation section separately from the transfer transistor; and
a third charge accumulation section that temporarily accumulates signal charges transferred by the additional transfer transistor.
(16)

The light detection device according to (1), further including: a switching transistor configured to electrically couple the first charge accumulation section or the second charge accumulation section to an additional capacitance.
(17)

A method for controlling a light detection device including a pixel array section in which a plurality of pixels is arranged in an array, the method including:
generating a signal charge of an amount corresponding to light incident from an outside by a photoelectric conversion film included in each of the plurality of pixels;
setting a first charge accumulation section that receives and accumulates the signal charge generated by the photoelectric conversion film and a second charge accumulation section that temporarily accumulates a signal charge transferred by a transfer transistor to a same potential;
setting the first charge accumulation section and the second charge accumulation section to different potentials at least during an accumulation period of the signal charge;
setting a gate voltage of the transfer transistor to be switched to a third voltage at which the signal charge overflows from the first charge accumulation section to the second charge accumulation section between a first voltage to be turned on and a second voltage to be turned off and lower than the first voltage during a period in which the first charge accumulation section and the second charge accumulation section are set to different potentials; and
setting a gate voltage of the transfer transistor to be switched from the third voltage to the first voltage or the second voltage at a time of reading the signal charge.
(18)

An electronic apparatus including:
a light detection device; and
a control unit configured to perform control on the basis of a pixel signal based on a signal charge read out by the light detection device, in which
the light detection device includes:
a pixel array section in which a plurality of pixels is arranged in an array, and
each of the plurality of pixels includes:
a photoelectric conversion film that generates a signal charge of an amount corresponding to light incident from an outside;
a first charge accumulation section that is connected to the photoelectric conversion film and receives and accumulates the signal charge;
a transfer transistor that is connected to the photoelectric conversion film and the first charge accumulation section and transfers the signal charge accumulated in the first charge accumulation section;
a second charge accumulation section that temporarily accumulates signal charges transferred by the transfer transistor; and
a potential difference generation section that generates a potential difference between the first charge accumulation section and the second charge accumulation section, and
a gate voltage of the transfer transistor is set to be switched to a first voltage to be turned on, a second voltage to be turned off and lower than the first voltage, and a third voltage between the first voltage and the second voltage, the third voltage causing the signal charge to overflow from the first charge accumulation section to the second charge accumulation section.
(19)

The electronic apparatus according to (18,) in which the control unit controls the potential difference generation section, calculates a voltage to be set to the first charge accumulation section or the second charge accumulation section and the third voltage to be set to a gate voltage of the transfer transistor according to a set condition, calculates an offset amount to be added to the pixel signal, and corrects the pixel signal on the basis of the offset amount.

### REFERENCE SIGNS LIST

1, 1A Light detection device
11 Pixel array section
12 Vertical drive section
13 Column processing section
14 Horizontal drive section
15 System control section
16 Signal processing section
17 Data storage section
18 Pixel drive line
19 Vertical signal line (VSL)
110, 110A, 110B, 110C, 110D, 110E, 110F, 110G Pixel
151 Control logic circuit
152 Voltage generation circuit
153 Overflow voltage generation circuit
154 Thermometer
1101 Photoelectric conversion film
1102 First charge accumulation region (SN)
1103 Transfer transistor
1104 Second charge accumulation region (FD)
1105 Reset transistor
1106 Amplification transistor (AMP)
1106 Amplification transistor
1107 Selection transistor
1108 Charge discharge transistor
1109 Voltage generation circuit
1110 Shared transistor
1111 Transfer transistor
1112 Reset transistor
1113 Charge discharge transistor
1114 Reset transistor
1115 Additional transfer transistor
1116 Third charge accumulation region (GM)
1117 Voltage generation circuit
1121 Additional capacitance section (SN2)
1122 Switching transistor
1123 Voltage generation circuit
2201 Imaging device
2202 Optical system
2203 Shutter device
2204 Solid-state imaging element
2205 Control circuit
2206 Signal processing circuit
2207 Monitor
2208 Memory
11109 Voltage generation circuit
12000 Vehicle control system
12001 Communication network
12010 Driving system control unit
12020 Body system control unit
12030 Outside-vehicle information detecting unit
12031 Imaging section
12040 In-vehicle information detecting unit
12041 Driver state detecting section
12050 Integrated control unit
12051 Microcomputer
12052 Sound/image output section
12061 Audio speaker
12062 Display section
12063 Instrument panel
12100 Vehicle
12101 to 12105 Imaging section
12111 to 12114 Imaging range

1. A light detection device comprising:
a pixel array section in which a plurality of pixels is arranged in an array, wherein
each of the plurality of pixels includes:
a photoelectric conversion film that generates a signal charge of an amount corresponding to light incident from an outside;
a first charge accumulation section that is connected to the photoelectric conversion film and receives and accumulates the signal charge;
a transfer transistor that is connected to the photoelectric conversion film and the first charge accumulation section and transfers the signal charge accumulated in the first charge accumulation section;
a second charge accumulation section that temporarily accumulates signal charges transferred by the transfer transistor; and
a potential difference generation section that generates a potential difference between the first charge accumulation section and the second charge accumulation section, and
a gate voltage of the transfer transistor is set to be switched to a first voltage to be turned on, a second voltage to be turned off and lower than the first voltage, and a third voltage between the first voltage and the second voltage, the third voltage causing the signal charge to overflow from the first charge accumulation section to the second charge accumulation section.

2. The light detection device according to claim 1, further comprising: a charge discharge transistor configured to discharge the signal charge.

3. The light detection device according to claim 2, wherein the charge discharge transistor is connected to the first charge accumulation section.

4. The light detection device according to claim 2, wherein the charge discharge transistor is connected to the second charge accumulation section.

5. The light detection device according to claim 1, further comprising: a reset transistor that resets potentials of the first charge accumulation section and the second charge accumulation section.

6. The light detection device according to claim 2, wherein the charge discharge transistor is connected to the second charge accumulation section, and is also used in common with a reset transistor that resets potentials of the first charge accumulation section and the second charge accumulation section.

7. The light detection device according to claim 2, wherein a gate voltage of the charge discharge transistor is higher than the third voltage set to a gate voltage of the transfer transistor by 1 V or less, and is set to be switched to the overflowing fourth voltage.

8. The light detection device according to claim 4, wherein a gate voltage of the charge discharge transistor is higher than the third voltage set to a gate voltage of the transfer transistor, and is set to be switched to the overflowing fourth voltage.

9. The light detection device according to claim 2, wherein in a case where the signal charge includes an electron, the transfer transistor and the charge discharge transistor include transistors of a first conductivity type.

10. The light detection device according to claim 9, wherein in a case where the signal charge includes a hole, the transfer transistor and the charge discharge transistor include transistors of a second conductivity type having a polarity opposite to the first conductivity type.

11. The light detection device according to claim 1, wherein the potential difference generation section is connected to at least one of the first charge accumulation section and the second charge accumulation section, and generates a potential difference between the first charge accumulation section and the second charge accumulation section.

12. The light detection device according to claim 1, wherein the potential difference generation section is connected to both the first charge accumulation section and the second charge accumulation section, and generates a potential difference between the first charge accumulation section and the second charge accumulation section.

13. The light detection device according to claim 5, wherein the potential difference generation section changes a drain voltage of the reset transistor at a drive timing.

14. The light detection device according to claim 1, wherein the potential difference generation section changes a voltage to be applied to the photoelectric conversion film at a drive timing.

15. The light detection device according to claim 1, further comprising: an additional transfer transistor that is connected to the first charge accumulation section or the second charge accumulation section and transfers the signal charge accumulated in the first charge accumulation section or the second charge accumulation section separately from the transfer transistor; and
a third charge accumulation section that temporarily accumulates signal charges transferred by the additional transfer transistor.

16. The light detection device according to claim 1, further comprising: a switching transistor configured to electrically couple the first charge accumulation section or the second charge accumulation section to an additional capacitance.

17. A method for controlling a light detection device including a pixel array section in which a plurality of pixels is arranged in an array, the method comprising:
generating a signal charge of an amount corresponding to light incident from an outside by a photoelectric conversion film included in each of the plurality of pixels;
setting a first charge accumulation section that receives and accumulates the signal charge generated by the photoelectric conversion film and a second charge accumulation section that temporarily accumulates a signal charge transferred by a transfer transistor to a same potential;
setting the first charge accumulation section and the second charge accumulation section to different potentials at least during an accumulation period of the signal charge;
setting a gate voltage of the transfer transistor to be switched to a third voltage at which the signal charge overflows from the first charge accumulation section to the second charge accumulation section between a first voltage to be turned on and a second voltage to be turned off and lower than the first voltage during a period in which the first charge accumulation section and the second charge accumulation section are set to different potentials; and
setting a gate voltage of the transfer transistor to be switched from the third voltage to the first voltage or the second voltage at a time of reading the signal charge.

18. An electronic apparatus comprising:
a light detection device; and
a control unit configured to perform control on a basis of a pixel signal based on a signal charge read out by the light detection device, wherein
the light detection device includes:
a pixel array section in which a plurality of pixels is arranged in an array, and
each of the plurality of pixels includes:
a photoelectric conversion film that generates a signal charge of an amount corresponding to light incident from an outside;
a first charge accumulation section that is connected to the photoelectric conversion film and receives and accumulates the signal charge;
a transfer transistor that is connected to the photoelectric conversion film and the first charge accumulation section and transfers the signal charge accumulated in the first charge accumulation section;
a second charge accumulation section that temporarily accumulates signal charges transferred by the transfer transistor; and
a potential difference generation section that generates a potential difference between the first charge accumulation section and the second charge accumulation section, and
a gate voltage of the transfer transistor is set to be switched to a first voltage to be turned on, a second voltage to be turned off and lower than the first voltage, and a third voltage between the first voltage and the second voltage, the third voltage causing the signal charge to overflow from the first charge accumulation section to the second charge accumulation section.

19. The electronic apparatus according to claim 18, wherein the control unit controls the potential difference generation section, calculates a voltage to be set to the first charge accumulation section or the second charge accumulation section and the third voltage to be set to a gate voltage of the transfer transistor according to a set condition, calculates an offset amount to be added to the pixel signal, and corrects the pixel signal on a basis of the offset amount.
